(19) United States
(12) Patent Application Publication
(10) Pub. No.: US 2026/0121640 A1
(43) Pub. Date: Apr. 30, 2026

(54) SEMICONDUCTOR DEVICE

(71) Applicant: ABLIC Inc., Nagano (JP)

(72) Inventors: Toshio NOMURA, Nagano (JP); Tomoki HIKICHI, Nagano (JP)

(73) Assignee: ABLIC Inc., Nagano (JP)

(21) Appl. No.: 19/353,591

(22) Filed: Oct. 8, 2025

(30) Foreign Application Priority Data
Oct. 29, 2024 (JP) 2024-189852

(51) Int. Cl. H03K 19/003

(52) U.S. Cl. CPC H03K 19/00315

(57) ABSTRACT

A semiconductor device (1) includes power terminals (VDD, GND), a voltage detection circuit (11), transistors (12, 13, 14), a depletion transistor (15), a control circuit (16), input ports (12a, 14a) connected to an output port (11b), input ports (11a, 16b) connected to the power terminal (VDD), a source end (12b), input ports (11c, 16c) connected to the power terminal (GND), source ends (14c, 15c), a gate end (15a), a source end (13b) connected to a drain end (12c), a gate end (13a) connected to a drain end (13c), drain ends (14b, 15b), and an input port (16a). Even in the case where a power supply voltage input to the voltage detection circuit (11) is equal to or lower than a minimum operating voltage of the voltage detection circuit (11), a signal received by the input port (16a) of the control circuit (16) matches a potential of the input terminal (GND).

### CROSS-REFERENCE TO RELATED APPLICATION

This application claims the priority benefits of Japanese application no. 2024-189852, filed on Oct. 29, 2024. The entirety of the above-mentioned patent application is hereby incorporated by reference herein and made a part of this specification.

### BACKGROUND

### Technical Field

The present invention relates to a semiconductor device.

### Related Art

In conventional semiconductor devices, in the case of a low voltage value of the supplied power supply voltage, a reference voltage source in a voltage detection circuit provided in a semiconductor device cannot output a target voltage, and may erroneously output a voltage detection signal. As a countermeasure for this case, an erroneous output range detection circuit capable of detecting that the voltage value of the power supply voltage is in a range where erroneous output occurs is separately provided, and a logic circuit is configured to perform a logic operation on a signal output from the erroneous output range detection circuit and the voltage detection signal, thereby preventing erroneous output of the voltage detection signal in the case of a low voltage value of the power supply voltage.

However, in conventional semiconductor devices, although logic circuits generally have a lower minimum voltage at which they may operate than analog circuits, in the case of an extremely low voltage value of the power supply voltage, the logic circuit itself may not operate, and there is a possibility that the result of the logic operation may not be output correctly.

### SUMMARY

### Technical Problem

The present invention provides a semiconductor device capable of reliably obtaining a correct voltage detection signal as long as the power supply voltage supplied to the semiconductor device is equal to or greater than OV.

### Solution to Problem

A semiconductor device according to an embodiment of the present invention includes: a voltage detection circuit, which includes a first input terminal, a second input terminal, a first input port connected to the first input terminal, a second input port connected to the second input terminal, and an output port, and in a case of comparing a potential difference input to the first input port and the second input port with a reference voltage of a predetermined potential, the voltage detection circuit outputs a first level detection signal in response to the potential difference input to the first input port and the second input port being lower than the reference voltage of the predetermined potential, and outputs a second level detection signal in response to the potential difference input to the first input port and the second input port being higher than the reference voltage of the predetermined potential; a first transistor including a gate end connected to the output port of the voltage detection circuit, a source end connected to the first input terminal, and a drain end; a second transistor including a gate end connected to the output port of the voltage detection circuit, a source end connected to the second input terminal, and a drain end; a voltage drop element including a first terminal connected to the drain end of the first transistor and a second terminal connected to the drain end of the second transistor; and a current source including a first terminal connected to the second terminal of the voltage drop element and a second terminal connected to the second input terminal, the current source operating even in the case where a power supply voltage is OV. Even in a case where a potential difference between the first input terminal and the second input terminal is lower than a minimum operating voltage of the voltage detection circuit and a potential of the output port of the voltage detection circuit is indefinite, a voltage output to the first terminal of the current source matches a potential of the second input terminal.

### Effects

According to the present invention, a correct voltage detection signal can be reliably obtained as long as the power supply voltage supplied to the semiconductor device is equal to or greater than OV.

### BRIEF DESCRIPTION OF THE DRAWINGS

FIG. 1 is a circuit diagram illustrating a semiconductor device according to an embodiment of the present invention.

FIG. 2 is a circuit diagram illustrating a conventional semiconductor device.

FIG. 3A is a characteristic diagram illustrating the relationship between the potential which is input to an input port of a control circuit and a power supply voltage in a conventional semiconductor device and FIG. 3B is a characteristic diagram illustrating the relationship between the potential which is input to an input port of a control circuit and a power supply voltage in a semiconductor device according to an embodiment of the present invention.

### DESCRIPTION OF THE EMBODIMENTS

Hereinafter, a semiconductor device according to an embodiment of the present invention will be described based on the drawings. For convenience of description, illustration of some configurations may be omitted or the scale may be changed.

### EMBODIMENT

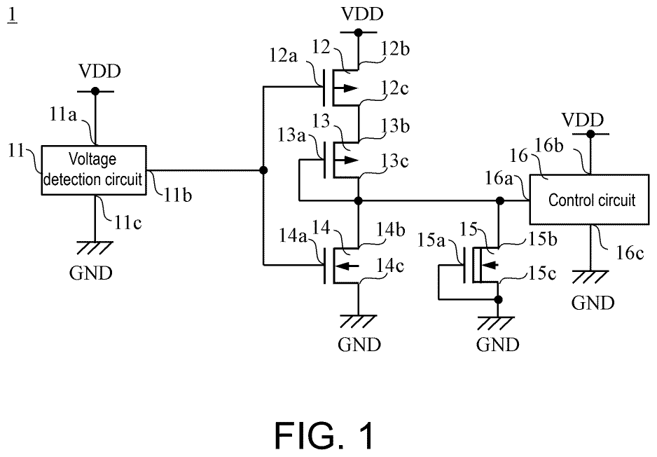

FIG. 1 is a circuit diagram illustrating a semiconductor device 1 which is an example of a semiconductor device according to the present embodiment.

The semiconductor device 1 includes a power terminal VDD and a power terminal GND, a voltage detection circuit 11, transistors 12, 13, 14, a depletion transistor 15, and a control circuit 16.

The voltage detection circuit 11 includes an input port 11a connected to the power terminal VDD, an input port 11c connected to the power terminal GND, and an output port 11b. The voltage detection circuit 11 is set with a low voltage detection voltage VDDL which serves as a threshold for outputting a predetermined logic from the output port 11b according to the magnitude of the potential difference between the input port 11a and the input port 11c. The voltage detection circuit 11 is configured such that in the case of the potential difference between the input port 11a and the input port 11c being equal to or greater than a minimum operating voltage VDDmin of the voltage detection circuit 11, the low voltage detection voltage VDDL is obtained as a predetermined threshold. For the voltage detection circuit 11, in the case of the potential difference between the input port 11a and the input port 11c being equal to or lower than the minimum operating voltage VDDmin, the potential of the output port 11b becomes indefinite; in the case of the potential difference being equal to or greater than VDDmin and equal to or lower than VDDL, the potential of the output port 11b matches the potential of the power terminal VDD; and in the case of the potential difference being equal to or greater than VDDL, the potential of the output port 11b matches the potential of the power terminal GND.

The transistor 12 includes a gate end 12a connected to the voltage detection circuit 11 (specifically to the output port 11b), a source end 12b connected to the power terminal VDD, and a drain end 12c.

The transistor 13 includes a source end 13b connected to the transistor 12 (specifically to the drain end 12c), a gate end 13a, and a drain end 13c, and the gate end 13a and the drain end 13c are short-circuited.

The transistor 14 includes a gate end 14a connected to the voltage detection circuit 11 (specifically to the output port 11b), a drain end 14b connected to the transistor 13 (specifically to the gate end 13a and the drain end 13c), and a source end 14c connected to the power terminal GND.

The depletion transistor 15 includes a drain end 15b connected to the transistor 13 to the transistor 14 (specifically to the gate end 13a and the drain end 13c, and the drain end 14b), a gate end 15a, and a source end 15c. The gate end 15a and the source end 15c are short-circuited, and even in the case of the potential difference between gate-source being 0, the transistor 15 becomes ON state and operates as a current source.

The control circuit 16 includes an input port 16a connected to the depletion transistor 15 (specifically to the gate end 13a and the drain end 13c, the drain end 14b, and the drain end 15b), an input port 16b connected to the power terminal VDD, and an input port 16c connected to the power terminal GND. In the case of the potential of the input port 16b of the control circuit 16 being lower than a predetermined threshold which is approximately half of the potential difference between the power terminal VDD and the power terminal GND, the control circuit 16 becomes standby state and its function is limited. Conversely, in the case of the potential being higher than the predetermined threshold which is approximately half, the control circuit 16 becomes active state and the limitation of function is released.

Next, the operation of the semiconductor device according to an embodiment of the present invention will be described using the semiconductor device 1 as an example. For an amplification stage composed of the transistor 12, the transistor 13, the transistor 14, and the depletion transistor 15, in the case of the potential difference between the power terminal VDD and the power terminal GND being small and the power supply voltage being equal to or lower than the minimum operating voltage VDDmin of the voltage detection circuit 11, the potential of the output port 11b of the voltage detection circuit 11 becomes indefinite, and also, the transistor 12 constituting the amplification stage cannot be turned ON, and even in the case that both the transistor 12 and the transistor 14 become OFF state, since the depletion transistor 15 is in ON state, the potential of the input port 16a of the control circuit 16 is fixed to GND, and the control circuit 16 reliably becomes standby state. Moreover, in the case of equal to or lower than the minimum operating voltage VDDmin of the voltage detection circuit 11 and an operating voltage sufficient to turn ON the transistor 12 and the transistor 13 is applied, in response to the potential of the output port 11b being indefinite, in the case where the potential of the input port 16a of the control circuit is set as V16a, and the following is expressed:

$$V 16 a = VDD min - VDS 12 - VDS 13 \qquad ( 1 )$$

Here, VDS12 is the potential difference between the drain end 12c and the source end 12b of the transistor 12, and VDS13 is the potential difference between the drain end 13c and the source end 13b of the transistor 13. VDS12 and VDS13 are determined by the current value flowing through the drain end 15b and the source end 15c of the depletion transistor 15. In the case of V16a expressed by equation (1) becoming V16a=VDDmin−VDS12−VDS13<VDDmin/2, the control circuit 16 becomes standby state, thus by determining an aspect ratio (W/L) of the transistor 12, the transistor 13, and the depletion transistor 15 so as to satisfy this relationship, the control circuit will not become active state in the case of the power supply voltage being equal to or lower than VDDmin.

In the case of gradually increasing the potential difference between the power terminal VDD and the power terminal GND to exceed the minimum operating voltage VDDmin of the voltage detection circuit 11, the potential of the output port 11b of the voltage detection circuit 11 matches the potential of the power terminal VDD. Since voltage detection circuits are generally composed of analog circuits, the minimum operating voltage VDDmin exceeds the ON voltage of the transistor 14. In this case, since both the transistor 14 and the depletion transistor 15 become ON state, the input port 16a of the control circuit 16 is more strongly fixed to the potential of the power terminal GND, and the standby state is maintained.

In the case of further increasing the potential difference between the power terminal VDD and the power terminal GND to become equal to or greater than VDDL, the potential of the output port 11b of the voltage detection circuit 11 matches the potential of the power terminal GND. At this time, in the case of VDDL being large enough to enable both the transistor 12 and the transistor 13 to become ON state, V16a which is the potential of the input port 16a of the control circuit 16 is expressed by the aforementioned equation (1). Since the control circuit 16 becomes active state in the case of the potential of the input port 16a being greater than half of the potential difference between the power terminal VDD and the power terminal GND, in order to make the control circuit 16 active state in the case of the potential of the power terminal VDD being VDDL, the potential of the input port 16a needs to be V16a=VDDL−VDS12−VDS13>VDDL/2. The aspect ratio (W/L) of the transistor 12, the transistor 13, and the depletion transistor 15 may be determined in any manner that satisfies this relationship.

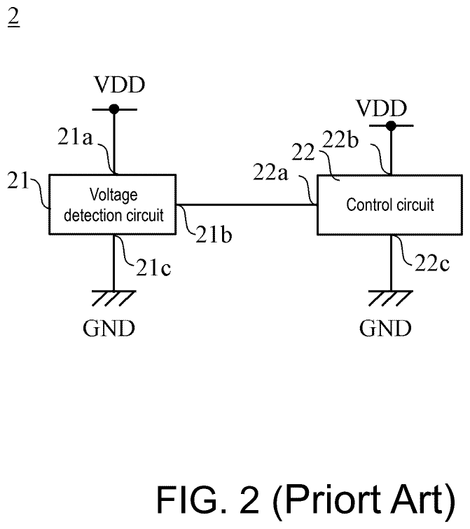

Next, the operation and effect of the semiconductor device 1 according to the present embodiment will be described while comparing with the operation of a conventional semiconductor device 2 (Comparative Example). FIG. 2 is a circuit diagram illustrating the semiconductor device 2 (Comparative Example).

The semiconductor device 2 (Comparative Example) includes a power terminal VDD, a power terminal GND, a voltage detection circuit 21, and a control circuit 22.

The voltage detection circuit 21 includes an input port 21a connected to the power terminal VDD, an input port 21c connected to the power terminal GND, and an output port 21b. For the voltage detection circuit 21, in the case of the potential difference between the input port 21a and the input port 21c being equal to or lower than the minimum operating voltage VDDmin, the potential of the output port 21b becomes indefinite; in the case of the potential difference being equal to or greater than VDDmin and equal to or lower than VDDL, the potential of the output port 21b matches the potential of the power terminal GND; and in the case of the potential difference being equal to or greater than VDDL, the potential matches the potential of the power terminal VDD.

The control circuit 22 includes an input port 22a connected to the voltage detection circuit 21 (specifically to the output port 21b), an input port 22b connected to the power terminal VDD, and an input port 22c connected to the power terminal GND. In the case of the potential of the input port 22a of the control circuit 22 being lower than a predetermined threshold which is approximately half of the potential difference between the power terminal VDD and the power terminal GND, the control circuit 22 becomes standby state and its function is limited. Conversely, in the case of the potential being higher than the predetermined threshold which is approximately half of the potential difference between the power terminal VDD and the power terminal GND, the control circuit 22 becomes active state and the limitation of function is released.

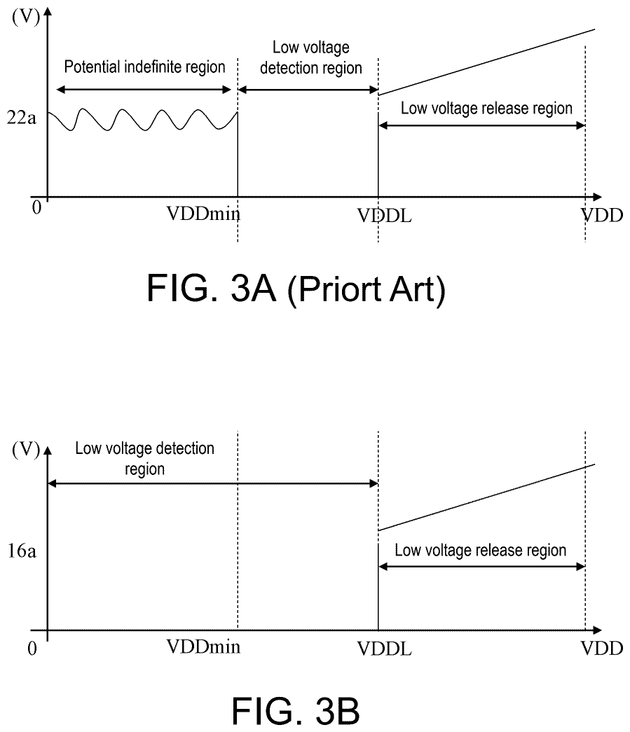

FIG. 3A and FIG. 3B are characteristic diagrams illustrating the relationship between the potential which is input to the input port of the control circuit and the power supply voltage in the semiconductor device 1 and in the conventional semiconductor device 2 (Comparative Example). As illustrated in the characteristic diagram FIG. 3A of the conventional semiconductor device 2 (Comparative Example), in the case of the power supply voltage input to the voltage detection circuit 21 being equal to or lower than VDDmin, the potential of the input port 22a of the control circuit 22 is expected to become the same potential as GND, but the operation of the analog circuit and logic circuit constituting the voltage detection circuit 21 is unstable, and the output port 21b of the voltage detection circuit 21 becomes HiZ state, and due to the influence of external noise, the potential input to the input port 22a of the control circuit 22 becomes indefinite. In the case of the potential of the input port 22a becoming indefinite, the control circuit 22 may take either the standby state or the active state, and thus may fall into an uncontrollable state.

On the other hand, in the semiconductor device 1, due to the effect of the amplification stage composed of the transistor 12, the transistor 13, the transistor 14, and the depletion transistor 15, even in the case of the power supply voltage input to the voltage detection circuit 11 being equal to or lower than VDDmin, as illustrated in the characteristic diagram FIG. 3B, the potential of the input port 16a of the control circuit 16 does not become indefinite and is fixed to GND. Thus, the input port 16a of the control circuit 16 is fixed to GND until the power supply voltage becomes VDDL, and may be maintained in the standby state, allowing complete control.

As described above, according to the semiconductor device 1, even in the case of the power supply voltage being equal to or lower than VDDmin and the potential of the output port 11b of the voltage detection circuit 11 being indefinite, due to the effect of the amplification stage composed of the transistor 12, the transistor 13, the transistor 14, and the depletion transistor 15, the potential of the input port 16a of the control circuit 16 is fixed to GND, and the control circuit 16 may be controlled as intended.

The present invention is not limited to the above-described embodiment as it is, and in the implementation stage, it may be implemented in various forms other than the above-described examples, and various omissions, additions, replacements, or changes may be made without departing from the gist of the invention. For example, the transistor 13 may be replaced with an element (resistor, diode, etc.) that causes a voltage drop according to current flow. Moreover, for example, the depletion transistor 15 may be replaced with a current source that operates even in the case where the power supply voltage is OV.

Moreover, in the semiconductor device 1, in response to the voltage of a signal received by the input port 16a of the control circuit 16 being equal to or greater than a predetermined threshold which is approximately half of the voltage input to the power terminal VDD and the power terminal GND, the control circuit 16 becomes an active state, and in response to the voltage being equal to or lower than the predetermined threshold which is approximately half, the control circuit 16 becomes a standby state. However, it may also be that in response to the voltage being equal to or greater than half of the voltage input to the power terminal VDD and the power terminal GND, the control circuit 16 becomes a standby state, and in response to the voltage being equal to or lower than half, the control circuit 16 becomes an active state. Moreover, the polarities of the transistor 12, the transistor 13 (or element that causes voltage drop), the transistor 14, and the depletion transistor 15 (or current source) may be reversed.

These embodiments and their modifications are included in the scope and gist of the invention, and are included in the invention described in the patent claims and the equivalent scope thereof.

What is claimed is:

1. A semiconductor device, comprising;
a voltage detection circuit including a first input terminal, a second input terminal, a first input port connected to the first input terminal, a second input port connected to the second input terminal, and an output port, and in a case of comparing a potential difference input to the first input port and the second input port with a reference voltage of a predetermined potential, the voltage detection circuit is capable of outputting a first level detection signal in response to the potential difference input to the first input port and the second input port being lower than the reference voltage of the predetermined potential, and is capable of outputting a second level detection signal in response to the potential difference input to the first input port and the second input port being higher than the reference voltage of the predetermined potential;
a first transistor including a gate end connected to the output port of the voltage detection circuit, a source end connected to the first input terminal, and a drain end;
a second transistor including a gate end connected to the output port of the voltage detection circuit, a source end connected to the second input terminal, and a drain end;
a voltage drop element including a first terminal connected to the drain end of the first transistor and a second terminal connected to the drain end of the second transistor; and
a current source including a first terminal connected to the second terminal of the voltage drop element and a second terminal connected to the second input terminal, the current source being configured to operate even in a case where a power supply voltage is OV;
wherein even in a case where a potential difference between the first input terminal and the second input terminal is lower than a minimum operating voltage of the voltage detection circuit and a potential of the output port of the voltage detection circuit is indefinite, a voltage output to the first terminal of the current source matches a potential of the second input terminal.

2. The semiconductor device according to claim 1, wherein the voltage drop element is a resistor including the first terminal connected to the drain end of the first transistor and the second terminal connected to the drain end of the second transistor.

3. The semiconductor device according to claim 1, wherein the voltage drop element is a third transistor including a source end connected to the drain end of the first transistor, and a drain end and a gate end connected to the drain end of the second transistor.

4. The semiconductor device according to claim 1, wherein the voltage drop element is a diode including the first terminal connected to the drain end of the first transistor and the second terminal connected to the drain end of the second transistor.

5. The semiconductor device according to claim 1, wherein the current source is a depletion transistor including a drain end connected to the first terminal, and a gate end and a source end connected to the second terminal.
